(19) United States
(12) Patent Application Publication
(10) Pub. No.: US 2009/0141472 A1
(43) Pub. Date: Jun. 4, 2009

(54) Adhesive composition for die bonding in semiconductor assembly, adhesive film prepared therefrom, device including the same, and associated methods

(76) Inventors: Han Nim Choi, Seoul (KR); Ki Tae Song, Gunpo-si (KR); Tae Shin Eom, Seongnam-si (KR); Chang Beom Chung, Yongin-si (KR)

Correspondence Address: LEE & MORSE, P.C., 3141 FAIRVIEW PARK DRIVE, SUITE 500, FALLS CHURCH, VA, 22042, US

(21) Appl. No.: 12/289,302

(22) Filed: Oct. 24, 2008

(30) Foreign Application Priority Data
Oct. 24, 2007 (KR) 10-2007-0107250

(51) Int. Cl. H05K 7/00; C09J 163/00; B32B 27/38; B32B 37/12

(52) U.S. Cl. 361/820; 523/467; 428/354; 156/330

(57) ABSTRACT

An adhesive film for semiconductor assembly includes a binder portion 1, a sub-binder portion, and a cured portion, wherein the binder portion 1 and the sub-binder portion co-exist in a co-continuous phase structure after curing begins.

### BACKGROUND OF THE INVENTION

1. Field of the Invention

Embodiments relate to an adhesive composition for die bonding in semiconductor assembly, an adhesive film prepared therefrom, a device including the same, and associated methods.

2. Description of the Related Art

Silver (Ag) paste has been used to bond a semiconductor device with a supporting element. Silver paste has some disadvantages including, for example, abnormal conditions in wire bonding caused by protrusion or inclination of the semiconductor device, foaming, difficulty in adjusting a thickness of the Ag paste, etc. Therefore, silver paste has largely been replaced by an adhesive film.

An adhesive film for semiconductor assembly may be used in combination with a dicing film. The dicing film is a film for fixing a semiconductor wafer during a dicing process. The dicing process is typically followed by subsequent processes such as expanding, pickup (or lift off), and/or mounting. The dicing film may be formed by applying a UV-curable or other curable-type adhesive to a base film, e.g., a film having a polyvinyl chloride (PVC) or polyolefin-based structure, and laminating a PET based cover film on the coated film. The adhesive film for semiconductor assembly may be attached to a semiconductor wafer, and the dicing film, from which a cover film is removed, may be stacked thereon. The laminate may be subjected to a dicing process.

The semiconductor wafer may be placed and fixed on the combined adhesive film/dicing film, and then diced, separated from the dicing film, and packaged with the adhesive film as part of the package. The die and the adhesive film should be simultaneously removed from the dicing film during lift off. Also, air bubbles, which may be caused by a rough surface while attaching the die adhesive film to a rear side of the semiconductor wafer, should be minimized to avoid generating voids between the die and wafer, as such voids may lead to a decrease in reliability of a semiconductor device and failure thereof. The adhesive film should also provide insulation of conductive structures, e.g., wires, etc.

### SUMMARY OF THE INVENTION

Embodiments are therefore directed to an adhesive composition for die bonding in semiconductor assembly, an adhesive film prepared therefrom, a device including the same, and associated methods, which substantially overcome one or more of the problems due to the limitations and disadvantages of the related art.

It is therefore a feature of an embodiment to provide an adhesive film having a co-continuous phase structure, i.e., a binder portion and a curable portion wherein the binder portion includes two portions, i.e., a binder portion and a sub-binder portion, which co-exist in a co-continuous phase structure.

It is therefore another feature of an embodiment to provide a dicing die-bonding film, a device package, and a method of packaging a die using an adhesive layer that includes an adhesive film with a co-continuous phase structure.

At least one of the above and other features and advantages may be realized by providing a composition for an adhesive film used in semiconductor assembly, the composition including an acrylic polymer, an epoxy resin, a phenol-type curable resin, a curing catalyst, and a silane coupling agent and a filler, wherein curing the composition provides a cured composition having a co-continuous phase structure.

The composition may include about 10 to about 85 wt. % of the acrylic polymer, about 5 to about 40 wt. % of the epoxy resin, about 5 to about 40 wt. % of the phenol type curable resin, about 0.01 to about 10 wt. % of the curing catalyst, about 0.01 to about 10 wt. % of the silane coupling agent, and about 0.1 to about 60 wt. % of the filler.

The acrylic polymer may include at least one cross-linkable epoxy group and may have an epoxy equivalent weight of about 1,000 to about 10,000. The acrylic polymer may have a weight average molecular weight of about 100,000 to about 1,000,000.

The epoxy resin may include at least 50 wt. % of multi-functional epoxy groups. The phenol-type curable resin may include at least 50 wt. % of a phenol novolac resin portion. The filler may be treated silica having a hydrophobic surface.

At least one of the above and other features and advantages may also be realized by providing an adhesive film for semiconductor assembly, including a binder portion 1, a sub-binder portion, and a cured portion. The binder portion 1 and the sub-binder portion may co-exist in a co-continuous phase structure after curing begins.

The co-continuous phase structure may have the cured portion distributed over the entirety of the binder portion 1 and the sub-binder portion. The co-continuous phase structure may have the cured portion distributed over the entirety of the binder portion 1 and the sub-binder portion. The co-continuous phase structure may have two glass transition temperatures in a range of about 0° C. to about 500° C. The co-continuous phase structure may have a first glass transition temperature in a range of about 0° C. to about 90° C. and a second glass transition temperature in a range of about 190° C. to about 500° C. A difference in coefficients of thermal expansion before and after at least one glass transition temperature may be about 5 μm/(m° C.) to about 500 μm/(m° C.). The co-continuous phase structure may have a storage modulus at 25° C. of about 0.1 MPa to about 10 MPa, and have another storage modulus at 80° C. of about 0.01 MPa to about 0.10 MPa. The co-continuous phase structure may have a melt viscosity at 25° C. of about 1,000,000 to about 5,000,000 P, and may have a surface tack value of less than about 0.1 gf.

At least one of the above and other features and advantages may also be realized by providing a dicing die-bonding film, including a base film, a first adhesive layer on the base film, and a second adhesive layer on the first adhesive layer, wherein the second adhesive layer includes the adhesive film according to an embodiment.

At least one of the above and other features and advantages may also be realized by providing a device package, including a die, an adhesive layer, and a next-level substrate, wherein the die is bonded to the next-level substrate by the adhesive layer, and the adhesive layer includes the adhesive film according to an embodiment.

At least one of the above and other features and advantages may also be realized by providing a method of packaging a die, the method including providing a die and a next-level substrate, and bonding the die to the next-level substrate using an adhesive layer, wherein the adhesive layer includes the adhesive film according to an embodiment.

### BRIEF DESCRIPTION OF THE DRAWINGS

The above and other features and advantages will become more apparent to those of ordinary skill in the art by describing in detail example embodiments with reference to the attached drawings, in which:

FIG. 1 illustrates a schematic view of an cross section of a co-continuously phase-separated adhesive film according to an embodiment;

FIG. 2 illustrates Table 1 setting forth characteristics of Examples 1 to 3 and Comparative Examples 1 to 5;

FIG. 3 illustrates Table 2 setting forth additional characteristics of Examples 1 to 3 and Comparative Examples 1 to 5;

FIG. 4 illustrates Formulae 1 to 3; and

FIG. 5 illustrates a die bonded to a substrate using an adhesive film according to an embodiment.

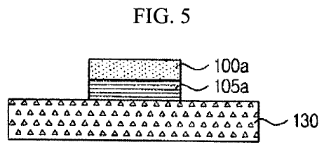

### DETAILED DESCRIPTION OF THE INVENTION

Korean Patent Application No. 10-2007-0107250, filed on Oct. 24, 2008, in the Korean Intellectual Property Office, and entitled: “Co-Continuously Phase-Separated Adhesive Composition for Die Bonding in Semiconductor Assembly and Adhesive Film Prepared Therefrom,” is incorporated by reference herein in its entirety.

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

As used herein, the expressions “at least one,” “one or more,” and “and/or” are open-ended expressions that are both conjunctive and disjunctive in operation. For example, each of the expressions “at least one of A, B, and C,” “at least one of A, B, or C,” “one or more of A, B, and C,” “one or more of A, B, or C” and “A, B, and/or C” includes the following meanings: A alone; B alone; C alone; both A and B together; both A and C together; both B and C together; and all three of A, B, and C together. Further, these expressions are open-ended, unless expressly designated to the contrary by their combination with the term “consisting of.” For example, the expression “at least one of A, B, and C” may also include an nth member, where n is greater than 3, whereas the expression “at least one selected from the group consisting of A, B, and C” does not.

As used herein, the expression “or” is not an “exclusive or” unless it is used in conjunction with the term “either.” For example, the expression “A, B, or C” includes A alone; B alone; C alone; both A and B together; both A and C together; both B and C together; and all three of A, B, and C together, whereas the expression “either A, B, or C” means one of A alone, B alone, and C alone, and does not mean any of both A and B together; both A and C together; both B and C together; and all three of A, B, and C together.

As used herein, the terms “a” and “an” are open terms that may be used in conjunction with singular items or with plural items. For example, the term “a curing catalyst” may represent a single compound, e.g., tetraphenylphosphonium tetraphenylborate, or multiple compounds in combination, e.g., tetraphenylphosphonium tetraphenylborate mixed with diphenylphosphinostyrene.

As used herein, molecular weights of polymeric materials are weight average molecular weights, unless otherwise indicated.

As used herein, the language “wt. % of the composition” is exclusive of solvent, unless otherwise indicated. That is, as used herein, the point of reference “the total amount of the adhesive film composition” does not include solvent. For example, where a composition is composed of two components A and B, with A present in 35 wt. % and B present in 65 wt. %, based on the total amount of the adhesive film composition, the addition of solvent to the composition would result in the composition continuing to have 35 wt. % A and 65 wt. % B, based on the total amount of the adhesive film composition.

A composition for fabricating an adhesive film, i.e., an adhesive composition, used in semiconductor assembly according to an embodiment may include an acrylic polymer, an epoxy resin, a phenol type curable resin, a curing catalyst, a silane coupling agent, and a filler. The adhesive composition may be used to form an adhesive film that is phase-separated into a co-continuous phase after curing.

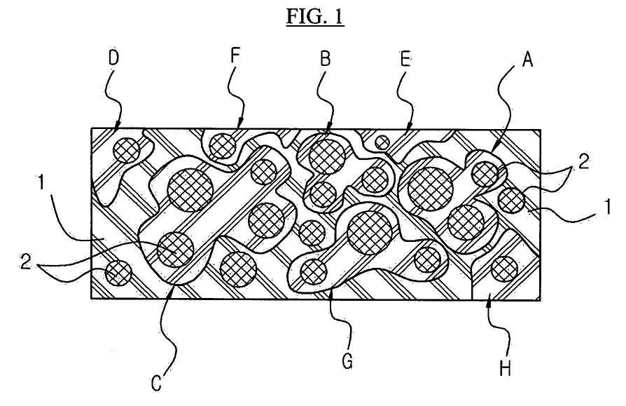

FIG. 1 illustrates a schematic view of a cross section of a co-continuously phase-separated adhesive film according to an embodiment.

Referring to FIG. 1, the co-continuously phase-separated adhesive film according to an embodiment may include a binder portion 1 having sub-binder portions A to H formed on the binder portion 1. The binder portion 1 and the sub-binder portions A to H may consist of substantially the same essential ingredients. The binder portion 1 and the sub-binder portions A to H may have a plurality of cured portions 2.

The binder portion 1 and the sub-binder portions A to H are co-continuously phase-separated. The co-continuously phase-separable structure is defined as at least two phases coexisting and 3-dimensionally penetrating each other, with each phase being substantially continuous. For example, sponge and the captured air inside it show a co-continuous structure. Thus, the terms “co-continuous phase-separated” and “co-continuous phase structure” mean that the binder portion 1 and the sub-binder portions A to H exist in a 3-dimensionally penetrating sponge-like structure. The cured portions 2 may exist in both the binder portion 1 and the sub-binder portions A to H. The binder portion 1 and the sub-binder portions A to H may consist of substantially the same essential ingredients. As curing progresses, the sub-binder portions A to H may be formed under desired conditions for curing reaction and/or environmental circumstances during the curing. For example, as curing progresses, a plurality of discrete small sub-binder portions A to H including acrylic polymer may be formed on the entirety of an acrylic polymer binder portion 1, depending on the curing degree of side chain functional groups in the acrylic polymer. Further, the cured portions 2 may be formed on the sub-binder portions A to H, and/or the cured portions 2 may be directly formed on the binder portion 1.

An adhesive film having a co-continuously phase-separable structure, i.e., a co-continuous phase, may provide several advantages. For example, voids between a semiconductor chip and the adhesive may be significantly reduced, and adhesive efficiency of the adhesive film may be improved and maintained by virtue of a desirable level of fluidity after the film is cured. Additionally, a polymer having an epoxy equivalent weight of about 1,000 to about 10,000 may easily form the co-continuous phase with the curable portion, thereby uniformly forming a wide area of a stable and co-continuous phase over the entirety of the adhesive film.

The co-continuous phase may also be effective to control a flow rate of an adhesive material on a semiconductor die, and may thus greatly reduce voids between the adhesive material and the die. As a result, the co-continuous phase may help enhance reliability of the adhesive film in terms of heat resistance and moisture resistance. Even if the content of the curable portion increases, thus accelerating a curing reaction, the co-continuous phase may allow a decrease in elastic modulus after curing and may control the flow rate so that foaming derived from slow curing, and the resultant decrease in reliability, can be prevented, thereby providing an adhesive film exhibiting desired levels of thermal resistance and moisture resistance. Moreover, an aging speed produced by a thermo-curable resin may be significantly reduced due to the co-continuous phase between the thermo-curable resin and a polymer resin, thus minimizing a decrease in adhesive strength caused by the aging. Therefore, the co-continuous phase may advantageously improve storage stability.

The co-continuous phase may exhibit two (2) glass transition temperatures. The two glass transition temperatures may be in a range of about 0° C. to about 500° C. Preferably, the co-continuous phase has a first glass transition temperature in a range of about 0° C. to about 90° C., and has a second glass transition temperature in a range of about 190° C. to about 500° C. More preferably, the co-continuous phase has the first glass transition temperature in a range of about 60° C. to about 90° C., and has the second glass transition temperature in a range of about 190° C. to about 220° C.

With regard to the co-continuously phase-separable structure of the adhesive film according to an embodiment, a glass transition temperature after curing, defined by an acrylic polymer and a curable portion in the film when the curable portion is present on the polymer portion in the co-continuous phase, is lower than that defined by the acrylic polymer and the curable portion coexisting in two discrete phases. This is because the polymer portion having a low glass transition temperature exerts influence on the co-continuous phase. Therefore, even using an adhesive with a decreased elastic modulus after curing and without thermoplastic properties exhibits sufficient fluidity to defoam or considerably reduce voids, thereby providing an adhesive film for semiconductor assembly with high reliability.

A difference in coefficient of thermal expansions (CTE), i.e., before and after the glass transition temperature Tg described above, may be about 5 to about 500 μm/(m° C.). Accordingly, thermal deformation derived from thermal shock may be minimized, resulting in favorably maintaining a connection reliability of the film.

The co-continuous phase may have a storage modulus of about 0.1 to about 10 MPa at 25° C. and about 0.10 to about 0.30 MPa at 60° C. Also, the co-continuous phase may have a melt viscosity (at 25° C.) of about 1,000,000 to about 5,000,000 P and a surface tacking value of less than about 0.1 g. Accordingly, two continuous phases formed while being cured do not show accelerated formation. Thus, curing at room temperature may be minimized. As a result, the co-continuous phase may be constantly maintained without variations in storage modulus and fluidity and/or surface tacking properties of the adhesive before curing. Accordingly, the co-continuous phase may provide beneficial effects on storage of the adhesive film at room temperature.

The adhesive composition according to an embodiment may include about 10 to about 85% by weight (“wt. %”) of the acrylic polymer, about 5 to about 40 wt. % of the epoxy resin, about 5 to about 40 wt. % of the phenol type curable resin, about 0.01 to about 10 wt. % of the curing catalyst, about 0.01 to about 10 wt. % of the silane coupling agent, and about 0.1 to about 60 wt. % of the filler.

### Acrylic Polymer

The acrylic polymer resin used in preferred embodiments is a rubber component that forms a film. The acrylic polymer may contain hydroxyl, carboxyl, or epoxy groups. Preferably, the adhesive polymer resin contains an epoxy group.

The acrylic polymer resin may have a glass transition temperature and molecular weight that is controlled by the selection of the monomers that are polymerized. Further, the acrylic polymer resin may be advantageous in that functional groups may be easily introduced to a side chain. Monomers used in polymerization (or copolymerization) may include one or more of, e.g., acrylonitrile, butyl acrylate, butyl methacrylate, 2-ethylhexyl acrylate, acrylic acid, 2-hydroxyethyl(meth)acrylate, methyl(meth)acrylate, styrene monomer, glycidyl(meth)acrylate, isooctylacrylate, stearylmethacrylate, etc.

The acrylic polymer resin may be classified based on epoxy equivalent weight, glass transition temperature, and/or molecular weight. Examples of commercially available products with an epoxy equivalent weight above 10,000 may include SG-80H (manufactured by Nagase ChemteX Corp.); SG-P3 series and/or SG-800H series products (also manufactured by Nagase ChemteX Corp.) may have an epoxy equivalent weight of less than 10,000.

The acrylic polymer resin may have at least one cross-linkable functional group having an epoxy equivalent weight of about 1,000 to about 10,000. Preferably, the epoxy equivalent weight ranges from about 2,000 to about 3,000. If the epoxy equivalent weight is less than about 1,000, it may be difficult to form a film. If the epoxy equivalent weight is more than about 10,000, the functional group may have compatibility problems with an epoxy or phenol portion, which may cause a decrease in reliability of the film.

The acrylic polymer resin may have a molecular weight of about 100,000 to about 1,000,000. The acrylic polymer resin preferably has a glass transition temperature Tg of about 0° C. to about 30° C. Such a glass transition temperature may prevent brittleness in the film at room temperature, and may inhibit occurrence of burrs or chipping during sawing during the manufacture of semiconductor dies.

The amount of the acrylic polymer resin in the adhesive composition for semiconductor assembly according to an embodiment may be about 10 to about 85 wt. % of total weight of the composition and, more preferably, about 15 to about 30 wt. %. If the amount is less than about 10 wt. %, it may be difficult to form a film. Conversely, if the amount is more than about 85 wt. %, the reliability of the film may be deteriorated.

### Epoxy Resin

The epoxy resin may include an epoxy resin having a high cross-linking density to impart strong curing and adhesive effects. A single curable epoxy system with a high cross-linking density may result in a brittle film. Accordingly, the epoxy resin may include a liquid-like epoxy resin, or a combination of mono- and/or di-functional epoxy resins, having low cross-linking densities.

The epoxy resin may have an equivalent weight of about 100 to about 1,500 g/eq., more preferably, about 150 to about 800 g/eq. and, most preferably, about 150 to about 400 g/eq. If the epoxy equivalent weight is less than about 100 g/eq., the cured adhesive may exhibit reduced adhesiveness. If the epoxy equivalent weight is more than about 1,500 g/eq., a decrease in glass transition temperature and/or a deterioration in thermal resistance of the epoxy resin may occur.

The epoxy resin may include an epoxy resin having at least one functional group, and may be in a solid or solid-like state, in view of film shapes. Preferred examples of the epoxy resin include bisphenol-type epoxy resins, ortho-cresol novolac-type epoxy resins, multi-functional epoxy resins, amine-type epoxy resins, heterocyclic epoxy resins, substitutional epoxy resins, and/or naphthol-type epoxy resins.

Particular examples of commercially available bisphenol-type epoxy resins may include: Epiclon 830-S, Epiclon EXA-830CRP, Epiclon EXA 850-S, Epiclon EXA-835LV, etc. (available from Dainippon Ink and Chemicals, Inc.); Epicoat 807, Epicoat 815, Epicoat 825, Epicoat 827, Epicoat 828, Epicoat 834, Epicoat 1001, Epicoat 1004, Epicoat 1007, Epicoat 1009, etc. (available from Yuka Shell Epoxy Co., Ltd.); DER-330, DER-301, DER-361, etc. (available from Dow Chemical Co.); and YD-128 or YDF-179 (available from Kukdo Chemical Co., Ltd.).

The ortho-cresol novolac-type epoxy resins may include: YDCN-500-1P, YDCN-500-4P, YDCN-500-5P, YDCN-500-7P, YDCN-500-80P, YDCN-500-90P, etc. (available from Kukdo Chemical Co., Ltd.); EOCN-102S, EOCN-103S, EOCN-104S, EOCN-1012, EOCN-1025, EOCN-1027, etc. (available from Nippon Kayaku Co., Ltd.).

The multifunctional epoxy resins may include: Epon 1031S (available from Yuka Shell Epoxy Co., Ltd.); Araldite 0163 (available from by Ciba Specialty Chemicals); and Detachol EX-611, Detachol EX-614, Detachol EX-614B, Detachol EX-622, Detachol EX-512, Detachol Ex-521, Detachol Ex-421, Detachol EX-411, Detachol EX-321, etc. (available from NAGA Celsius Temperature Co., Ltd.).

The amine-type epoxy resins may include: Epicoat 604 (available from Yuka Shell Epoxy Co., Ltd.); YH-434 (available from Kukdo Chemical Co., Ltd.); TETRAD-X or TETRAD-C (available from Mitsubishi Gas Chemical Company Inc.); and ELM-120 (available from Sumitomo Chemical Industry Co., Ltd.).

The heterocyclic epoxy resins may include: PT-810 (available from Ciba Specialty Chemicals).

The substitutional epoxy resins may include: ERL-4234, ERL-4299, ERL-4221, ERL-4206, etc. (available from UCC Co., Ltd.).

The naphthol-type epoxy resins may include: Epiclon HP-4032, Epiclon HP-4032D, Epiclon HP-4700, Epiclon HP-4701, etc. (available from Dainippon Ink and Chemicals, Inc.).

The epoxy resins may each be used alone, or as a combination of two or more thereof.

The epoxy resin may contain at least 50 wt. % of the multifunctional epoxy resin. If the content of the multifunctional epoxy resin is less 50 wt. %, the epoxy resin may have a low cross-linking density, which may decrease internal bonding strength of the resulting structure and reduce reliability.

The amount of epoxy resin in the adhesive composition according to an embodiment may be about 5 to about 40 wt. % of total weight of the adhesive composition. If the content is less than about 5 wt. %, the adhesive film may lack sufficient curable portions, leading to a decrease in reliability. If the content is more than about 40 wt. %, the adhesive film may exhibit reduced compatibility. The content of the epoxy resin is preferably less than 30 wt. % in order to reduce surface tacking properties of the adhesive film at room temperature, which in turn, decreases adhesion between the film and an adhesive during lift off, thereby reducing lift off effects.

### Phenol-Type Curable Resin

The phenol-type curable resin may include bisphenol A, F and/or S-type phenol curable resins having two or more phenolic hydroxyl groups in one molecule, which may provide excellent electrolytic corrosion resistance to moisture absorption. The phenol-type curable resin may also include phenol novolac, bisphenol A-type novolac or cresol novolac resins, xyloc-type resins, biphenyl-type resins, etc.

Preferred examples of the phenol-type curable resin include: H-1, H-4, HF-1M, HF-3M, HF-4M, HF-45, etc. (available from Meiwa Kasei Co., Ltd.) as simple phenol-type curable resins; MEH-78004S, MEF-7800SS, MEH-7800S, MEH-7800M, MEH-7800H, MEH-7800HH, MEH-78003H, etc. (available from Meiwa Kasei Co., Ltd.) as para-xylene-type resins; KPH-F3065 (available from KOLON Chemical Co., Ltd.); MEH-7851SS, MEH-7851S, MEH-7851M, MEH-7851H, MEH-78513H, MEH-78514H, etc. (available from Meiwa Kasei Co., Ltd.) as biphenyl-type resins; KPH-F4500 (available from KOLON Chemical Co., Ltd.); and MEH-7500, MEH-75003S, MEH-7500SS, MEH-7500H, etc. (available from Meiwa Kasei Co., Ltd.) as triphenylmethyl-type resins.

The phenol-type resins may each be used alone, or as a combination of two or more thereof.

In a preferred embodiment, the phenol-type curable resin is represented by the following Formula 1:

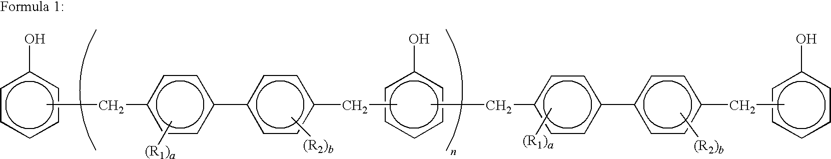

In Formula 1, R₁ and R₂ are each independently an alkyl group having 1 to 4 carbon atoms or a hydrogen atom; a and b are each independently an integer ranging from 0 to 4; and n is an integer ranging from 0 to 7.

The phenol-type curable resin represented by Formula 1 may have two or more hydroxyl groups in one molecule, and may provide excellent electrolytic corrosion resistance to moisture absorption, superior thermal resistance, low moisture absorption, and may exhibit excellent reflow resistance.

The phenol-type curable resin represented by Formula 1 preferably has a hydroxyl equivalent weight of about 100 to about 600 g/eq., and more preferably about 170 to about 300 g/eq. If the hydroxyl equivalent weight is less than about 100 g/eq., moisture absorption may increase, which may lead to deterioration of the reflow resistance. If the hydroxyl equivalent weight is more than about 600 g/eq., the glass transition temperature may decrease and the thermal resistance may deteriorate.

The phenol-type curable resin preferably contains at least 50 wt. % of a phenol novolac resin so that the curable resin may have an increased cross-linking density after curing, thereby increasing intermolecular cohesion. Increased intermolecular coadhesion may, in turn, increase internal bonding strength, thereby improving the adhesiveness of the composition. Moreover, the curable resin containing at least 50 wt. % of the phenol novolac resin may exhibit minimal deformation due to external stress, which may be advantageous in maintaining a constant thickness of the film.

The adhesive composition for semiconductor assembly according an example embodiment may include about 5 to about 40 wt. % of the phenol-type curable resin, based on the total weight of the composition.

### Curing Catalyst

The curing catalyst may be added to control a curing rate, and may include phosphine-based, boron-based, and imidazole-based catalysts. The curing catalyst may be included in an amount of about 0.01 to about 10 wt. % based on the total weight of the adhesive composition. More preferably, the amount of the curing catalyst may be about 0.01 to about 2 wt. % of the total weight of the adhesive composition for semiconductor assembly. If the amount of the curing catalyst exceeds about 10 wt. %, the storage stability of the composition may decrease.

The phosphine-based curing catalysts may include: triphenylphosphine, tri-o-tolylphosphine, tri-m-tolylphosphine, tri-p-tolylphosphine, tri-2,4-xylylphosphine, tri-2,5-xylylphosphine, tri-3,5-xylylphosphine, tribenzylphosphine, tris(p-methoxyphenyl)phosphine, tris(p-tert-butoxyphenyl)phosphine, diphenylcyclohexylphosphine, tricyclohexylphosphine, tricyclophosphine, tributylphosphine, tri-tert-butylphosphine, tri-n-octylphosphine, diphenylphosphinostyrene, diphenylphosphinous chloride, tri-n-octylphosphine oxide, diphenylphosphinyl hydroquinone, tetrabutylphosphonium hydroxide, tetrabutylphosphonium acetate, benzyltriphenylphosphonium hexafluoroantimonate, tetraphenylphosphonium tetraphenylborate, tetraphenylphosphonium tetra-p-tolylborate, benzyltriphenylphosphonium tetraphenylborate, tetraphenylphosphonium tetrafluoroborate, p-tolyltriphenylphosphonium tetra-p-tolylborate, triphenylphosphine triphenylborane, 1,2-bis(diphenylphosphino)ethane, 1,3-bis(diphenylphosphino)propane, 1,4-bis(diphenylphosphino)butane, 1,5-bis(diphenylphosphino)pentane, etc.

The boron-based curing catalysts may include: phenyl boronic acid, 4-methylphenyl boronic acid, 4-methoxyphenyl boronic acid, 4-methoxyphenyl boronic acid, 4-trifluoromethoxyphenyl boronic acid, 4-tert-butoxyphenyl boronic acid, 3-fluoro-4-methoxyphenyl boronic acid, pyridine-triphenylborane, 2-ethyl-4-methylimidazolium tetraphenylborate, 1,8-diazabicyclo[5.4.0]undecene-7-tetraphenylborate, 1,5-diazabicyclo[4.3.0]nonene-5-tetraphenylborate, lithium triphenyl(n-butyl)borate, etc.

The imidazole-based curing catalysts may include: 2-methylimidazole, 2-undecylimidazole, 2-heptadecylimidazole, 2-ethyl-4-methylimidazole, 2-phenylimidazole, 2-phenyl-4-methylimidazole, 1-benzyl-2-phenylimidazole, 1,2-dimethylimidazole, 1-cyanoethyl-2-methylimidazole, 1-cyanoethyl-2-ethyl-4-methylimidazole, 1-cyanoethyl-2-undecylimidazole, 1-cyanoethyl-2-phenylimidazole, 1-cyanoethyl-2-undecylimidazolium-trimellitate, 1-cyanoethyl-2-phenylimidazolium-trimellitate, 2,4-diamino-6[2′-methylimidazoyl-(1′)]-ethyl-s-triazine, 2,4-diamino-6-[2′-undecylimidazoyl-(1′)]-ethyl-s-triazine, 2,4-diamino-6-[2′-methylimidazoyl-(1′)]-ethyl-s-triazine isocyanuric acid adduct dehydrate, 2-phenylimidazole isocyanuric acid adduct, 2-methylimidazole isocyanuric acid adduct dehydrate, 2-phenyl-4,5-dihydroxymethylimidazole, 2-phenyl-4-methyl-5-hydroxymethylimidazole, 2,3-dihydro-1H-pyrrolo[1,2-a]benzimidazole, 4,4′-methylene-bis(2-ethyl-5-methylimidazole), 2-methylimidazoline, 2-phenylimidazoline, 2,4-diamino-6-vinyl-1,3,5-triazine, 2,4-diamino-6-vinyl-1,3,5-triazine isocyanuric acid adduct, 2,4-diamino-6-methacryloyloxyethyl-1,3,5-triazine isocyanuric acid adduct, 1-(2-cyanoethyl)-2-ethyl-4-methylimidazole, 1-cyanoethyl-2-methylimidazole, 1-(2-cyanoethyl)2-phenyl-4,5-di-(cyanoethoxymethyl)imidazole, 1-acetyl-2-phenylhydrazine, 2-ethyl-4-methyl imidazoline, 2-benzyl -4-methyl diimidazoline, 2-ethylimidazoline, 2-phenylimidazole, 2-phenyl-4,5-dihydroxymethylimidazole, melamine, dicyandiamide, etc. These catalysts may each be used alone or as a combination of two or more thereof.

The curing catalyst may include one or more compounds represented by the following Formulae 2 and 3:

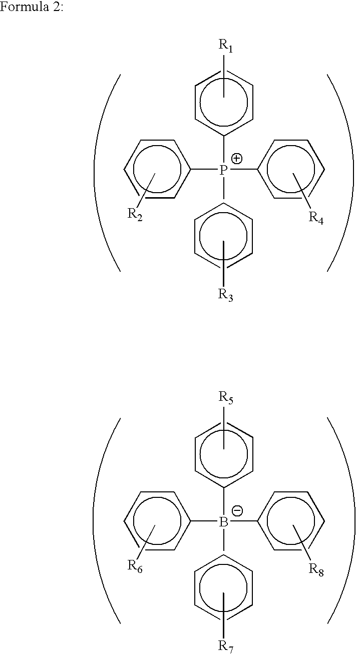

In Formula 2, R₁ to R₈ are each independently a hydrogen atom, a halogen atom or an alkyl group.

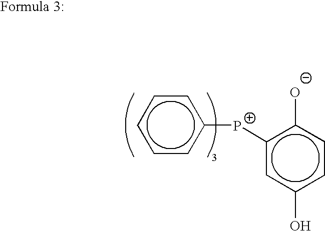

A curing catalyst including one or more compounds represented by Formulae 2 and 3 may have a higher temperature for initiating a curing reaction, as compared to that of an amine curing agent or an imidazole curing catalyst, which may be advantageous to provide a uniform curing rate and a relatively low reactivity at room temperature. Accordingly, the composition including such a curing catalyst may provide excellent storage stability. If using the phenol resin represented by Formula 1, using an amine curing agent and/or an imidazole-based curing catalyst may result in some curing during storage at room temperature for an extended period of time, which may affect curing properties and has the potential to produce voids and/or deterioration in adhesion during semiconductor assembly. In contrast, using a curing catalyst including one or more compounds represented by Formula 2 and 3 with the phenol resin represented by Formula 1 may inhibit the curing reaction from progressing at room temperature, which may reduce or eliminate failures in the semiconductor assembly caused by irregular curing properties. Also, an adhesive composition having a curing catalyst including one or more compounds represented by Formulae 2 and 3 may exhibit relatively low electrical conductivity, e.g., as compared to compositions containing an amine curing agent or the imidazole-based curing catalyst, and may exhibit excellent reliability during a “Pressure Cooker Test” (PCT).

### Silane Coupling Agent

The silane coupling agent may be added to the composition as an adhesion enhancer to increase adhesion between a surface of an inorganic material, such as silica, and a resin in an adhesive film. The silane coupling agent may include an epoxy group-containing silane, an amine group-containing silane, an isocyanate containing-silane, or a mercapto group-containing silane.

The epoxy group-containing silane may include one or more of, e.g., 2-(3,4-epoxycyclohexyl)-ethyltrimethoxysilane, 3-glycidoxytrimethoxysilane, and 3-glycidoxypropyl triethoxysilane.

The amine group-containing silane may include one or more of, e.g., N-2(aminoethyl)-3-aminopropyl trimethoxysilane, N-2(aminoethyl)-3-aminopropyl trimethoxysilane, N-2(aminoethyl)-3-aminopropyl triethoxysilane, 3-aminopropyltrimethoxysilane, 3-aminopropyltriethoxysilane, 3-triethoylsili-(1,3-dimethylbutylidene)propylamine, and N-phenyl-3-aminopropyltrimethoxysilane.

The mercapto group-containing silane may include one or more of, e.g., 3-mercaptopropylmethyl dimethoxysilane and 3-mercaptopropyltriethoxysilane.

The isocyanate containing-silane may include, e.g., 3-isocyanate propyltriethoxysilane.

The silane coupling agents may each be used alone, or as a combination of two or more thereof.

The silane coupling agent may be included in an amount of about 0.01 to about 10 wt. %, based on the total weight of the adhesive composition.

### Filler

The adhesive composition may further include a filler to provide thixotropic properties and control melt viscosity. The filler may include inorganic or organic fillers. The inorganic filler may include metallic components such as gold, silver, copper and/or nickel in a powder state, and inorganic components such as alumina, aluminum hydroxide, magnesium hydroxide, calcium carbonate, magnesium carbonate, calcium silicate, magnesium silicate, calcium oxide, magnesium oxide, aluminum oxide, aluminum nitride, silica, boron nitride, titanium dioxide, glass, ferrite, ceramic, etc. The organic filler may include carbon, rubber fillers, polymer-based fillers, etc. In an implementation, the filler may have a spherical surface with hydrophobic properties. Spherical silica particles may be used the filler, in which case the particles preferably have a particle size of about 500 nm to about 5 μm. A particle size of above 10 μm may impinge on a semiconductor circuit, thus causing damage to the circuit.

The amount of the filler used in the adhesive composition may be about 0.1 to about 60 wt. % of the total weight of the composition. The adhesive film for semiconductor assembly according to an embodiment may be used as a die adhesive film and, in this case, the amount of the filler preferably ranges from about 10 to about 40 wt. %. If the amount of filler is more than about 60 wt. %, it may be difficult to form an adhesive film, leading to deterioration in tensile strength of the film.

### Organic Solvent

The adhesive composition may further include an organic solvent. The organic solvent may reduce the viscosity of the composition, thereby easing fabrication of the adhesive film. Depending on a thickness of the film, the residual amounts of organic solvent in the adhesive composition may adversely affect physical properties of the composition. Accordingly, the organic solvent may have a boiling point of about 80° C. to about 140° C., and preferably includes one or more of butyl acetate, propylene glycol monomethylether acetate, acetone, methylethylketone (MEK), methyl isobutylketone (MIBK), tetrahydrofuran (THF), dimethylformamide (DMF), and cyclohexanone.

An embodiment also provides an adhesive film for semiconductor assembly fabricated using the adhesive composition described above. The adhesive film according to an embodiment may be co-continuously phase-separated.

Depending on the curing conditions, which may include, e.g., an epoxy equivalent weight of an acrylic polymer resin, a molecular weight of a polymer resin, and/or the presence or absence of an additional thermoplastic resin, the nature of the co-continuously phase-separable structure may be controlled in view of phase dimensions and a rate for fabrication of the structure.

If the epoxy equivalent weight of the acrylic polymer resin is more than about 10,000, there may be an increased tendency of the polymer resin to separate from curable portions, which may cause a division into two different phases rather than forming the co-continuously phase-separable structure. If the epoxy equivalent weight is less than about 1,000, the separation behavior between the polymer resin and the curable portions may be weakened so that both phases are combined rather than being separate. As to the molecular weight of the polymer resin, it has been determined that the phase separation is proportional to the molecular weight.

In general, a thermoplastic resin, which may be used for attaining high fluidity at high temperatures, mostly induces phase separation due to compatibility even before the adhesive film is cured and, in addition, accelerates the phase separation after the film is cured. With different contents of constitutional ingredients of the adhesive composition, increasing the ductile structure and tensile strength of the adhesive film can prevent cutting of the film and increase adhesion between semiconductor dies.

Increasing the amount of curable portions in the adhesive film may reduce the elastic modulus of the film, minimize voids generated when a chip is adhered to an interface of the film, and completely fill areas around wires, which may provide for improved reliability in the device package.

In an implementation, the co-continuously phase-separable structure of the adhesive film may be obtained by including in the adhesive composition an epoxy resin containing at least 50 wt. % of a multi-functional epoxy ingredient and a phenol-type curable resin containing at least 50 wt. % of a phenol novolac resin ingredient, so as to form a thermo-curable portion. The thermo-curable portion may be cured with an acrylic polymer resin having a ductile structure. The acrylic polymer resin may have a molecular weight of at least 500,000, and may contain at least one cross-linking functional group having an epoxy equivalent weight in a range of about 2,000 to about 3,000. Since the ductile structure and an improved tensile strength may be simultaneously provided even if a content of the curable portion increases, the film may maintain a desired hardness, may exhibit superior adhesion after molding with an epoxy molding compound (EMC) during a process for the semiconductor assembly, and may provide excellent reliability.

The adhesive film may include an attach void free type film, which may have voids of less than 5% generated during the die attaching process. The adhesive film may have a melt viscosity at a temperature for die attaching in a range of about 80,000 to about 100,000 P, and may have another melt viscosity at a temperature for filling uneven portions of a wire arranged on a semiconductor chip. The adhesive film may completely fill areas around wires.

Another embodiment provides a dicing die-bonding film including an adhesive film according to an embodiment. The dicing die-bonding film may include a base film, as well as an adhesive layer and an attachment film layer sequentially laminated on the base film. The adhesive layer may be, e.g., a UV-curable layer separable from the attachment film upon exposure to UV light. The attachment film layer may include an adhesive film fabricated according to an embodiment.

The adhesive layer of the dicing die-bonding film may be formed using a generally-known adhesive composition, which preferably includes about 100 parts by weight (“wt. parts”) of a polymer binder, about 20 to about 150 wt. parts of UV-curable acrylate relative to weight of the polymer binder, and about 0.1 to about 5 wt. parts of a photo initiator, relative to weight of the UV-curable acrylate.

The base film of the dicing die-bonding film may transmit radiation, e.g., UV light, and may be radiolucent. If the dicing die-bonding film includes a UV-curable adhesive, the base film may be prepared using at one or more polymeric materials exhibiting favorable light transmission. Such polymeric materials may include, for example, a polyolefin homopolymer or copolymer such as polyethylene, polypropylene, a propylene ethylene copolymer, an ethylene ethyl acrylate copolymer, an ethylene methyl acrylate copolymer, an ethylene vinyl acetate copolymer, etc., polycarbonate, polymethyl methacrylate, polyvinyl chloride, a polyurethane copolymer, etc. The base film preferably has a thickness of about 50 to about 200 μm in consideration of tensile strength, elongation, radiolucent properties, etc.

FIG. 6 illustrates a die bonded to a substrate using an adhesive film according to an embodiment. Referring to FIG. 6, an adhesive film 105a having a co-continuous phase structure may be disposed between a die 100a and a next-level substrate 130. The die may be, e.g., a semiconductor die, an optical or electro-optical die, a microelectromechanical system (MEMS) die, etc. The next-level substrate may be, e.g., a printed circuit board, an interposer, etc. The die 100a and the adhesive film 105a may be encapsulated, e.g., with an epoxy molding compound, etc., on the next-level substrate 130.

The following Examples and Comparative Examples are provided in order to set forth particular details of one or more embodiments. However, it will be understood that the embodiments are not limited to the particular details described.

### EXAMPLES 1 TO 3, COMPARATIVE EXAMPLES 1 TO 5

After adding the components described below to a 1L cylindrical flask equipped with a high speed impeller, the resulting mixture was dispersed under low speed agitation at 3000 rpm for 20 minutes and then high speed agitation at 4000 rpm for 5 minutes to prepare a composition. The composition was filtered using a capsule filter having a size of 50 μm and then applied to a base film using an applicator to fabricate an adhesive film with a thickness of 60 μm. After drying the fabricated film at 80° C. for 20 minutes and then at 90° C. for 20 minutes, the completed film was stored at room temperature for 1 day.

### EXAMPLE 1

Components: a) epoxy-containing acrylic polymer resin: KLS-104a (EEW=2,000 to 3,000), manufactured by Fujikura Kasei Co., Ltd., 220 g; b) multi-functional epoxy resin: EP-5100R, manufactured by Kukdo Chemical Co., Ltd., 80 g; c) phenol novolac curable resin: DL-92, manufactured by Meiwa Plastic Industries, Ltd., 60 g; d) phosphine based curing catalyst: TPP-K, TPP or TPP-MK, manufactured by Meiwa Plastic Industries, Ltd., 3.8 g; e) epoxy silane coupling agent: KBM-303, manufactured by Shin-Etsu Chemical Co., Ltd., 2.2 g; and f) spherical silica: SC-4500SQ, SC-2500SQ, manufactured by Admatechs Co., Ltd., 70 g.

### EXAMPLE 2

Components: a) epoxy-containing acrylic polymer resin: KLS-104a, manufactured by Fujikura Kasei Co., Ltd., 220 g; b) multi-functional epoxy resin: EP-5100R, manufactured by Kukdo Chemical Co., Ltd., 60 g; and bisphenol F type epoxy resin: YDF 2001, manufactured by Kukdo Chemical Co., Ltd., 20 g; c) phenol novolac curable resin: DL-92, manufactured by Meiwa Plastic Industries, Ltd., 60 g; d) phosphine based curing catalyst: TPP-K, TPP or TPP-MK, manufactured by Meiwa Plastic Industries, Ltd., 3.8 g; e) epoxy silane coupling agent: KBM-303, manufactured by Shin-Etsu Chemical Co., Ltd., 2.2 g; and f) spherical silica: SC-4500SQ, SC-2500SQ, manufactured by Admatechs Co., Ltd., 70 g.

### EXAMPLE 3

Components: a) epoxy-containing acrylic polymer resin: KLS-104a, manufactured by Fujikura Kasei Co., Ltd., 220 g; b) multi-functional epoxy resin: EP-5100R, manufactured by Kukdo Chemical Co., Ltd., 80 g; c) xylene based phenol type curable resin: 7800 4S, manufactured by Meiwa Plastic Industries, Ltd., 60 g; d) phosphine based curing catalyst: TPP-K, TPP or TPP-MK, manufactured by Meiwa Plastic Industries, Ltd., 3.8 g; e) epoxy silane coupling agent: KBM-303, manufactured by Shin-Etsu Chemical Co., Ltd., 2.2 g; and f) spherical silica: SC-4500SQ, SC-2500SQ, manufactured by Admatechs Co., Ltd., 70 g.

### COMPARATIVE EXAMPLE 1

Components: a) epoxy-containing acrylic polymer resin: KLS-104a (EEW=2,000 to 3,000), manufactured by Fujikura Kasei Co., Ltd., 380 g; b) multi-functional epoxy resin: EP-5100R, manufactured by Kukdo Chemical Co., Ltd., 7 g; c) phenol novolac curable resin: DL-92, manufactured by Meiwa Plastic Industries, Ltd., 8.5 g; d) phosphine based curing catalyst: TPP-K, TPP or TPP-MK, manufactured by Meiwa Plastic Industries, Ltd., 2.2 g; e) epoxy silane coupling agent: KBM-303, manufactured by Shin-Etsu Chemical Co., Ltd., 1.2 g; and f) spherical silica: SC-4500SQ, SC-2500SQ, manufactured by Admatechs Co., Ltd., 40 g.

### COMPARATIVE EXAMPLE 2

Components: a) epoxy-containing elastomer resin: KLS-105a (EEW=900), manufactured by Fujikura Kasei Co., Ltd., 220 g; b) multi-functional epoxy resin: EP-5100R, manufactured by Kukdo Chemical Co., Ltd., 80 g; c) phenol novolac curable resin: DL-92, manufactured by Meiwa Plastic Industries, Ltd., 60 g; d) phosphine based curing catalyst: TPP-K, TPP or TPP-MK, manufactured by Meiwa Plastic Industries, Ltd., 3.8 g; e) epoxy silane coupling agent: KBM-303, manufactured by Shin-Etsu Chemical Co., Ltd., 2.2 g; and f) spherical silica: SC-4500SQ, SC-2500SQ, manufactured by Admatechs Co., Ltd., 70 g.

### COMPARATIVE EXAMPLE 3

Components: a) epoxy-containing elastomer resin: KLS-104b (EEW=12,000), manufactured by Fujikura Kasei Co., Ltd., 220 g; b) multi-functional epoxy resin: EP-5100R, manufactured by Kukdo Chemical Co., Ltd., 80 g; c) phenol novolac curable resin: DL-92, manufactured by Meiwa Plastic Industries, Ltd., 60 g; d) phosphine based curing catalyst: TPP-K, TPP or TPP-MK, manufactured by Meiwa Plastic Industries, Ltd., 3.8 g; e) epoxy silane coupling agent: KBM-303, manufactured by Shin-Etsu Chemical Co., Ltd., 2.2 g; and f) spherical silica: SC-4500SQ, SC-2500SQ, manufactured by Admatechs Co., Ltd., 70 g.

### COMPARATIVE EXAMPLE 4

Components: a) epoxy-containing acrylic polymer resin: KLS-104a (EEW=2,000 to 3,000), manufactured by Fujikura Kasei Co., Ltd., 220 g; b) bisphenol F type di-functional epoxy resin: YDF-2001, manufactured by Kukdo Chemical Co., Ltd., 80 g (containing 0% multi-functional epoxy resin); c) phenol novolac curable resin: DL-92, manufactured by Meiwa Plastic Industries, Ltd., 60 g; d) phosphine based curing catalyst: TPP-K, TPP or TPP-MK, manufactured by Meiwa Plastic Industries, Ltd., 3.8 g; e) epoxy silane coupling agent: KBM-303, manufactured by Shin-Etsu Chemical Co., Ltd., 2.2 g; and f) spherical silica: SC-4500SQ, SC-2500SQ, manufactured by Admatechs Co., Ltd., 70 g.

### COMPARATIVE EXAMPLE 5

Components: a) epoxy-containing acrylic polymer resin: KLS-104a, manufactured by Fujikura Kasei Co., Ltd., 220 g; b) multi-functional epoxy resin: EP-5100R, manufactured by Kukdo Chemical Co., Ltd., 20 g; and bisphenol F type epoxy resin: YDF-2001, manufactured by Kukdo Chemical Co., Ltd., 60 g (containing 30% multi-functional epoxy resin); c) phenol novolac curable resin: DL-92, manufactured by Meiwa Plastic Industries, Ltd., 60 g; d) phosphine based curing catalyst: TPP-K, TPP or TPP-MK, manufactured by Meiwa Plastic Industries, Ltd., 3.8 g; e) epoxy silane coupling agent: KBM-303, manufactured by Shin-Etsu Chemical Co., Ltd., 2.2 g; and f) spherical silica: SC-4500SQ, SC-2500SQ, manufactured by Admatechs Co., Ltd., 70 g.

### Evaluation and Characterization of Films Fabricated in Examples and Comparative Examples

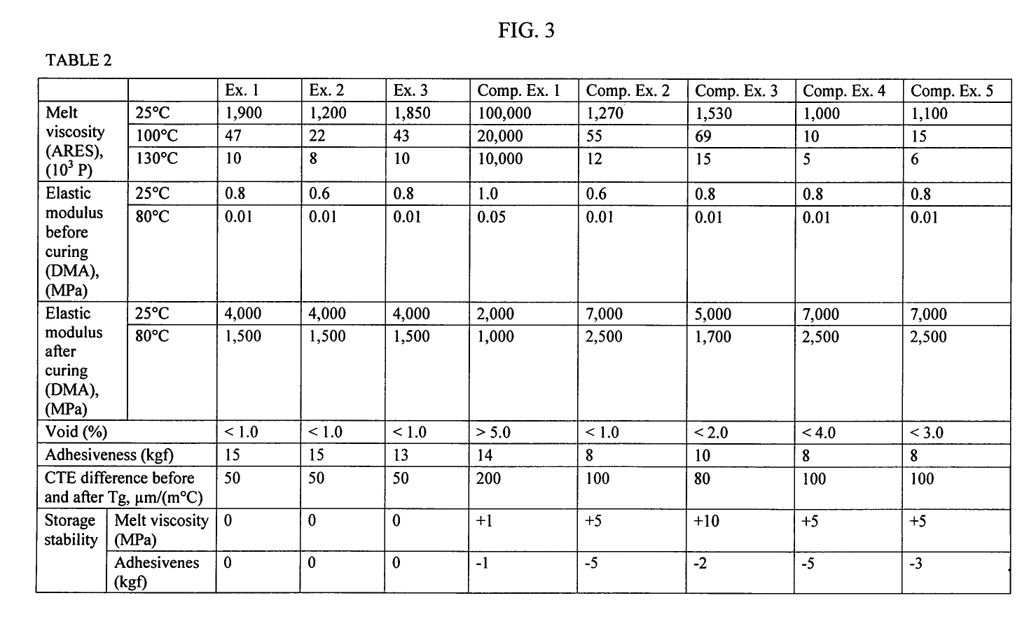

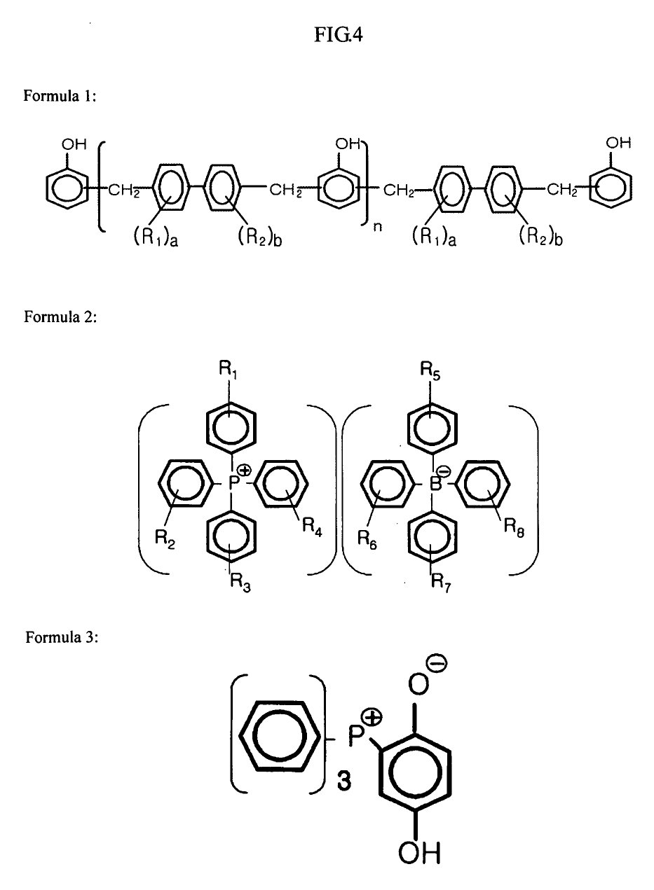

Evaluation and characterization was performed with respect to each film for fabricated in Examples 1 to 3 and Comparative Examples 1 to 5 according to the procedure described below. The results are shown in Tables 1 and 2 in FIGS. 3 and 4, respectively. However, for identification of the phase structure (Evaluation no. 1 below), the identification was performed using the adhesive composition itself, rather than the adhesive film made therefrom.

### (1) Identification of Phase Structure 1:

The liquid adhesive composition was applied to a glass plate having a size of 18 mm×18 mm to coat the plate to a thickness of 60 to 80 μm. The coated plate was placed on a hot plate at 80° C. for 10 minutes, followed by heating the hot plate to a temperature of 125° C. Following this, the coated plate was cured at 125° C. for 1 hour then at 175° C. for 2 hours. A turbidity of each coated portion in the cured plate was observed. Table 1 shows whether there was a variation in turbidities or not, as denoted by “o” and “x”, respectively.

### (2) Identification of Phase Structure 2:

Each adhesive film was cut to a size of 20 mm×20 mm. The cut film was cured at 125° C. for 1 hour then at 175° C. for 3 hours, followed by grinding lateral sides of the film. A structure of the cured film was determined via Scanning Electron Microscopy (SEM). Table 1 shows whether there was a co-continuously phase-separable structure or not, as denoted by “o” and “x”, respectively.

### (3) Determination of Glass Transition Temperature After Curing:

Each adhesive film was fabricated by laminating four adhesive layers together at 60° C., followed by cutting the film to a size of 5.5 mm×15 mm. The cut film had a thickness of 200 to 300 μm. After completely curing the cut film, the cured film was subjected to temperature evaluation while elevating the temperature from −50 to 300° C. at 4° C./min. The evaluation was performed using a dynamic mechanical analyzer (DMA; TA Instruments model Q800). After the evaluation, a temperature range for peaks and the number of peaks in the range were observed. Table 1 shows the number of separated phases.

### (4) Determination of Melt Viscosity:

In order to determine a viscosity of each adhesive film, each adhesive film was fabricated by laminating four adhesive layers together at 60° C. and then cutting a round piece having a diameter of 25 mm and a thickness of 400 to 440 μm. The film was subjected to melt viscosity determination while elevating the temperature from 30 to 130° C. at 5° C./min. Table 2 shows Eta values at different temperatures, particularly including: 25° C. before curing; at 100° C. as a die attach temperature at which fluidity is determined; and at 130° C. at which filling of uneven portions around a wire is determined.

### (5) Determination of Voids:

A wafer having a thickness of 725 μm having a dioxide film coating was cut to a size of 5 mm×5 mm. The prepared wafer piece was laminated with an adhesive film at 60° C., followed by cutting the laminate to obtain an adhesive-coated wafer piece. A glass plate having a thickness of 15 μm and a size of 18 mm×18 mm was placed on a hot plate at 100° C., followed by compressing the wafer piece to the glass plate at 1.0 kgf for 1.0 second. The appearance of air bubbles on the wafer piece was observed by microscopy.

### (6) Determination of Elastic Modulus Before and After Curing:

In order to determine the elastic modulus of each adhesive film, each adhesive film was fabricated by laminating four adhesive layers together at 60° C., and cutting to a size of 25 mm and a thickness of 400 to 440 μm before curing (200 to 300 μm after curing). After the curing was completed, the cured film was subjected to elastic modulus determination while elevating the temperature from 30 to 260° C. at 4° C./min. The determination was performed using a DMA (TA Instruments model Q800).

### (7) Determination of Adhesive Ability:

A wafer having a thickness of 725 μm having a dioxide film coating was cut to a size of 5 mm×5 mm. The prepared wafer piece was laminated with an adhesive film at 60° C., followed by cutting the laminate to obtain an adhesive-coated wafer piece. Another wafer having a thickness of 725 μm and a size of 10 mm×10 mm, which was coated with a photosensitive polyimide, was placed on a hot plate at 100° C., followed by compressing the former wafer piece to the latter wafer at 1.0 kgf for 1.0 second. The compression was repeated at 125° C. for 1 hour and then at 175° C. for 3 hours. The treated wafer piece was subjected to determination of fracture strength at 270° C. following moisture absorption for 48 hours at 85° C. and 85% RH.

### (8) Determination of Coefficient of Thermal Expansion (CTE):

Each adhesive film was fabricated by laminating four adhesive layers together at 60° C., followed by cutting the film to a size of 5.5 mm×15 mm. The cut film had a thickness of 200 to 300 μm. After completely curing the cut film, the cured film was subjected to CTE determination while elevating the temperature from −50 to 300° C. at 4° C./min. The determination was performed using a DMA (TA Instruments model Q800).

### (9) Determination of Storage Stability:

After storing each film at room temperature for 30 days, the film was subjected to determination of a melt viscosity at 100° C. and the adhesive ability of the film was evaluated. The measurement results are shown in Table 2, as a variation relative to an initially-measured value.

As shown in Table 1, each of the adhesive films in Examples 1 to 3 was fabricated using a composition which included an acrylic polymer resin having a molecular weight of at least 100,000, at least one cross-linkable epoxy group with an epoxy equivalent weight of 2,000 to 3,000, and containing at least 50 wt. % of a multi-functional epoxy ingredient. Each of the adhesive films in Examples 1 to 3 was identified as having a co-continuous phase structure after curing (see FIG. 1).

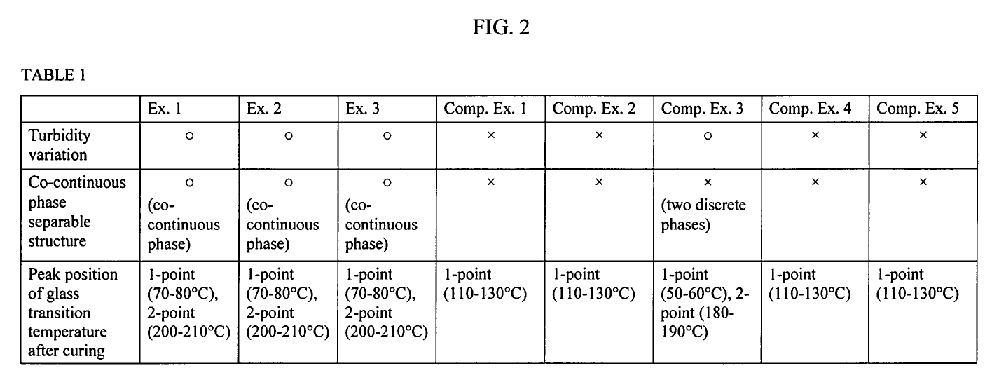

A co-continuous phase structure was not found in each of the adhesive films in Comparative Examples 1, 2, 4 and 5. For the adhesive film of Comparative Example 3, although phase separation was observed, the adhesive film had two discrete phases instead of the co-continuous phase structure (see FIG. 2).

As shown in Table 2, each of the adhesive films prepared in the Comparative Examples as well as the Examples had pre-curing physical properties that substantially depended on the original characteristics of constitutional ingredients. All adhesive films prepared in Examples 1 to 3 and Comparative Examples 2 to 5 were “attach void free type” films, having voids of less than 5% generated by die-attaching. The adhesive film prepared in Comparative Example 1 was not an “attach void free type” film. Among the “attach void free type” films, the films in Comparative Examples 2, 4 and 5 showed no phase separation, while each adhesive film in Examples 1 to 3 had a co-continuous phase structure.

The adhesive films in Examples 1 to 3 had a ductile structure and an improved tensile strength even with an increased content of a curable portion, which may prevent the film from being cut and may maintain improved hardness.

As compared to the film in Comparative Example 3 having two discrete phases, the adhesive films of Examples 1 to 3 having a co-continuous phase structure showed a desired fluidity after curing, which may lead to a decrease in elastic modulus after the film is cured so that the film has an advantage of improving and maintaining adhesive efficiency. Moreover, the adhesive films of Examples 1 to 3 having a co-continuous phase structure may provide improved reliability by virtue of increased thermal resistance and moisture resistance of the film because of the improved adhesive efficiency. Therefore, the adhesive films of Examples 1 to 3 may provide high adhesiveness and favorable thermal stability derived from improved moisture resistance after EMC molding in a process for semiconductor assembly, thereby ensuring excellent reliability in semiconductor assembly.

With regard to CTE values before and after curing, each adhesive film in Examples 1 to 3 exhibited a relatively low difference in CTE values before and after curing, as compared to the adhesive films in Comparative Examples 2 to 5. Thus, the co-continuous phase structure of Examples 1 to 3 may minimize thermal deformation of a semiconductor assembly having a laminated structure after curing, thereby enhancing the reliability of connections in the assembly, particularly as compared to a single phase (Comparative Examples 2, 4 and 5) and/or two discrete phases (Comparative Example 3). Consequently, the adhesive films of Examples 1 to 3 may avoid decreases in reliability caused by thermal shrinkage.

With regard to storage stability, the adhesive film having a co-continuous phase (Examples 1 to 3) exhibits excellent storage stability, while the films having a single phase (Comparative Examples 2, 4 and 5) and/or two discrete phases (Comparative Example 3) readily undergo aging. In the case of the two discrete phases, a contact time between a curing enhancer and a curable portion increases during phase separation so as to accelerate curing, resulting in an increased frequency in potential occurrence of the curing at room temperature thus exhibiting a variation in viscosities at room temperature. Conversely, for the co-continuous phase, formation of the co-continuous phase is not accelerated during curing and, thus, an effect of the curing potentially occurring at room temperature can be minimized. As a result, the adhesive film may be favorably maintained at room temperature without variations in storage modulus, fluidity, and/or surface tacking properties of the adhesive before curing. Accordingly, the adhesive film having a co-continuous phase may provide improved storage at room temperature.

As described above, the adhesive composition according to embodiments may be useful for fabricating an adhesive film having a co-continuously phase-separable film structure after curing. The fabricated adhesive film may simultaneously provide a ductile structure and an improved tensile strength, even with an increased content of a curable portion, thereby exhibiting an improved hardness without being cut. Therefore, the adhesive film according to embodiments may exhibit superior adhesion after EMC molding in a process for semiconductor assembly, ensuring excellent reliability in semiconductor assembly. Also, film shrinkage may not occur between semiconductor chips, the adhesive film may avoid a shrinkage problem. Moreover, the adhesive film may provide an “attach void free type” film based on high fluidity at high temperatures and may completely fill around a wire, thereby ensuring excellent reliability in semiconductor assembly.

As described above, the binder resin (acrylic polymer) has many epoxy functional groups. Thus, during curing, the binder portion can be separated into the binder portion 1 (which is not reacted with phenolic curable resin and curing catalysts) and the sub-binder portions (which are reacted and partly cured with phenolic curable resin and curing catalysts). In the binder portion, the binder portion 1 and the sub binder portions A˜H (see FIG. 1) exist in co-continuous structure, which is sponge-air like structure. The sub-binder portions may be reacted, and at least partly cured, from the acrylic polymer, the phenol type curable resin, and the curing catalyst. Accordingly, the adhesive film according to embodiments is phase-separated into a co-continuous phase providing the combined properties of a polymer and a curable portion of the film.

Exemplary embodiments of the present invention have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A composition for an adhesive film used in semiconductor assembly, the composition comprising:
an acrylic polymer;
an epoxy resin;
a phenol-type curable resin;
a curing catalyst; and
a silane coupling agent and a filler, wherein curing the composition provides a cured composition having a co-continuous phase structure.

2. The composition as claimed in claim 1, wherein the composition includes:
about 10 to about 85 wt. % of the acrylic polymer,
about 5 to about 40 wt. % of the epoxy resin,
about 5 to about 40 wt. % of the phenol type curable resin,
about 0.01 to about 10 wt. % of the curing catalyst,
about 0.01 to about 10 wt. % of the silane coupling agent, and
about 0.1 to about 60 wt. % of the filler.

3. The composition as claimed in claim 1, wherein the acrylic polymer includes at least one cross-linkable epoxy group and has an epoxy equivalent weight of about 1,000 to about 10,000.

4. The composition as claimed in claim 1, wherein the acrylic polymer has a weight average molecular weight of about 100,000 to about 1,000,000.

5. The composition as claimed in claim 1, wherein the epoxy resin includes at least 50 wt. % of multi-functional epoxy groups.

6. The composition as claimed in claim 1, wherein the phenol-type curable resin includes at least 50 wt. % of a phenol novolac resin portion.

7. The composition as claimed in claim 1, wherein the filler is treated silica having a hydrophobic surface.

8. An adhesive film for semiconductor assembly, comprising:
a binder portion 1;
a sub-binder portion; and
a cured portion, wherein the binder portion 1 and the sub-binder portion co-exist in a co-continuous phase structure after curing begins.

9. The adhesive film as claimed in claim 8, wherein the co-continuous phase structure has the cured portion distributed over the entirety of the binder portion 1 and the sub-binder portion.

10. The adhesive film as claimed in claim 8, wherein the co-continuous phase structure has two glass transition temperatures in a range of about 0° C. to about 500° C.

11. The adhesive film as claimed in claim 10, wherein the co-continuous phase structure has a first glass transition temperature in a range of about 0° C. to about 90° C. and a second glass transition temperature in a range of about 190° C. to about 500° C.

12. The adhesive film as claimed in claim 11, wherein a difference in coefficients of thermal expansion before and after at least one glass transition temperature is about 5 μm/(m° C.) to about 500 μm/(m° C.).

13. The adhesive film as claimed in claim 8, wherein the co-continuous phase structure has a storage modulus at 25° C. of about 0.1 MPa to about 10 MPa, and has another storage modulus at 80° C. of about 0.01 MPa to about 0.10 MPa.

14. The adhesive film as claimed in claim 8, wherein the co-continuous phase structure has a melt viscosity at 25° C. of about 1,000,000 to about 5,000,000 P, and has a surface tack value of less than about 0.1 gf.

15. A dicing die-bonding film, comprising:
a base film;
a first adhesive layer on the base film; and
a second adhesive layer on the first adhesive layer, wherein the second adhesive layer includes the adhesive film as claimed in claim 8.

16. A device package, comprising:
a die;
an adhesive layer; and
a next-level substrate, wherein:
the die is bonded to the next-level substrate by the adhesive layer, and
the adhesive layer includes the adhesive film as claimed in claim 8.

17. A method of packaging a die, the method comprising:
providing a die and a next-level substrate; and
bonding the die to the next-level substrate using an adhesive layer, wherein:
the adhesive layer includes the adhesive film as claimed in claim 8.
